(19) United States
(12) Patent Application Publication
(10) Pub. No.: US 2025/0107420 A1
(43) Pub. Date: Mar. 27, 2025

(54) METHOD OF MANUFACTURING HEAT DISSIPATION ADHESIVE LAYER FOR DISPLAY DEVICE AND DISPLAY DEVICE INCLUDING THE SAME

(71) Applicant: Samsung Display Co., Ltd., Yongin-Si (KR)

(72) Inventors: Hui Yeon SHON, Yongin-si (KR); Hyun Joon OH, Yongin-si (KR); Jae Suk YOO, Yongin-si (KR); Jae Sang LEE, Yongin-si (KR); Jee Na LEE, Yongin-si (KR); Kwang Sig JUNG, Yongin-si (KR)

(21) Appl. No.: 18/735,179

(22) Filed: Jun. 6, 2024

(30) Foreign Application Priority Data
Sep. 25, 2023 (KR) 10-2023-0127652

(51) Int. Cl. H10K 59/80; H10K 59/12; H10K 102/00

(52) U.S. Cl. CPC H10K 59/8794; H10K 59/1201; H10K 59/8722; H10K 2102/351

(57) ABSTRACT

A method of manufacturing a heat dissipation adhesive layer for a display device is disclosed that includes providing a liner, a first coating layer on the liner, and a heat dissipation layer on the first coating layer, forming a mask dam surrounding the heat dissipation layer, and forming a second coating layer inside the mask dam.

### CROSS-REFERENCE TO RELATED APPLICATION

This application claims priority from Korean Patent Application No. 10-2023-0127652 filed on Sep. 25, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method of manufacturing a heat dissipation adhesive layer for the same.

### 2. Description of the Related Art

As the information society has developed, the demand for display devices has increased and diversified. Display devices include liquid crystal displays (LCDs), field emission displays (FEDs), and light emitting displays (LEDs). Light emitting displays include organic light emitting displays in which light emitting elements are organic light emitting diode elements and inorganic light emitting displays in which the light emitting elements are inorganic light emitting diode elements.

Light emitting displays are widely used in mobile electronic devices such as smartphones, and are easily exposed to external shocks. In addition, when excessive heat is generated from the light emitting elements or a driving chip that drives the light emitting elements or other components, there is a risk that the light emitting elements will be damaged. To protect display devices from such a risk, a cover panel having functions such as a heat dissipation function and a buffer function may be attached as a member to a lower surface of a display panel.

### SUMMARY

Aspects of the present disclosure provide a display device capable of minimizing a delamination phenomenon of a heat dissipation layer, and a method of manufacturing a heat dissipation adhesive layer for the same.

Aspects of the present disclosure also provide a display device capable of preventing a step of a heat dissipation layer from being viewed, and a method of manufacturing a heat dissipation adhesive layer for the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

An embodiment of a method of manufacturing a heat dissipation adhesive layer for a display device includes providing a liner, a first coating layer on the liner, and a heat dissipation layer on the first coating layer; forming a mask dam surrounding the heat dissipation layer; and forming a second coating layer inside the mask dam.

In an embodiment, the heat dissipation layer includes a body portion and an opening hole penetrating through the body portion.

In an embodiment, the second coating layer fills the opening hole.

In an embodiment, an upper surface of the second coating layer includes a ridge portion overlapping the body portion and a valley portion overlapping the opening hole.

In an embodiment, a height difference between the ridge portion and the valley portion is 5 μm or less.

In an embodiment, the second coating layer includes a flat portion and a sloped portion disposed on one side of the flat portion.

In an embodiment, an upper surface of the second coating layer includes a ridge portion and a valley portion positioned at a lower level than the ridge portion, and in the flat portion, a height difference between the ridge portion and the valley portion is 5 μm or less.

In an embodiment, the method of manufacturing a heat dissipation adhesive layer for a display device may further comprise cutting the second coating layer along an inner side of the mask dam.

In an embodiment, a cutting line of the second coating layer overlaps the flat portion of the second coating layer.

In an embodiment, an upper surface of the second coating layer is higher than an upper surface of the mask dam.

In an embodiment, the second coating layer covers at least a portion of the upper surface of the mask dam.

In an embodiment, a thickness of the mask dam is greater than or equal to a thickness of the second coating layer.

In an embodiment, the mask dam is directly disposed on an upper surface of the first coating layer.

In an embodiment, the mask dam is directly disposed on an upper surface of the liner, and surrounds the first coating layer.

In an embodiment, an inner side surface of the mask dam is spaced apart from a side surface of the first coating layer.

An embodiment of a display device includes a display panel, and a panel lower member including a heat dissipation adhesive layer and disposed on a rear surface of the display panel, wherein the heat dissipation adhesive layer includes a first coating layer, a heat dissipation layer disposed on the first coating layer, and a second coating layer covering the heat dissipation layer, and an upper surface of the second coating layer is a flat surface.

In an embodiment, the upper surface of the second coating layer includes a ridge portion and a valley portion, and the ridge portion is positioned at a higher level than the valley portion.

In an embodiment, a height difference between the ridge portion and the valley portion is 10% or less of a thickness of the second coating layer.

In an embodiment, the height difference between the ridge portion and the valley portion is 5 μm or less.

In an embodiment, the panel lower member further includes, a shielding layer, an adhesive layer disposed on the shielding layer, and a buffer layer disposed on the adhesive layer, and the heat dissipation adhesive layer is disposed on the buffer layer.

With a display device and a method of manufacturing the same according to an embodiment of the present disclosure, it is possible to minimize a delamination phenomenon of a heat dissipation layer.

With the display device and the method of manufacturing the same according to an embodiment of the present disclosure, it is possible to prevent a step of the heat dissipation layer from being viewed.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an electronic device according to an embodiment;

FIG. 2 is a perspective view illustrating a display device included in the electronic device according to an embodiment;

FIG. 3 is a cross-sectional view illustrating the display device according to an embodiment;

FIG. 4 is a cross-sectional view illustrating a display panel according to an embodiment;

FIG. 5 is a cross-sectional view illustrating a panel lower member according to an embodiment;

FIG. 6 is a plan view illustrating a heat dissipation adhesive layer according to an embodiment;

FIG. 7 is a cross-sectional view taken along line X1-X1′ of FIG. 6;

FIG. 8 is an enlarged view of area A of FIG. 7;

FIG. 9 is a photograph of a graph illustrating flatness of a heat dissipation adhesive layer according to the related art;

FIG. 10 is a photograph of a graph illustrating flatness of the heat dissipation adhesive layer according to an embodiment;

FIG. 11 is a flowchart illustrating a method of manufacturing a heat dissipation adhesive layer for a display device according to an embodiment;

FIG. 12 is a cross-sectional view illustrating S100 of FIG. 11;

FIG. 13 is a cross-sectional view illustrating S200 of FIG. 11;

FIG. 14 is a cross-sectional view illustrating S300 of FIG. 11;

FIG. 15 is a plan view illustrating S400 of FIG. 11;

FIG. 16 is a cross-sectional view illustrating S400 of FIG. 11;

FIG. 17 is a cross-sectional view illustrating S400_1 of a method of manufacturing a heat dissipation adhesive layer for a display device according to another embodiment;

FIG. 18 is a cross-sectional view illustrating S400_2 of a method of manufacturing a heat dissipation adhesive layer for a display device according to still another embodiment;

FIG. 19 is a cross-sectional view illustrating S500 of FIG. 11;

FIG. 20 is a cross-sectional view illustrating S500_1 of a method of manufacturing a heat dissipation adhesive layer for a display device according to another embodiment;

FIG. 21 is a cross-sectional view illustrating S500_2 of a method of manufacturing a heat dissipation adhesive layer for a display device according to still another embodiment;

FIG. 22 is a cross-sectional view illustrating S600 of FIG. 11; and

FIG. 23 is a cross-sectional view illustrating S600 of FIG. 11.

### DETAILED DESCRIPTION OF THE EMBODIMENTS

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

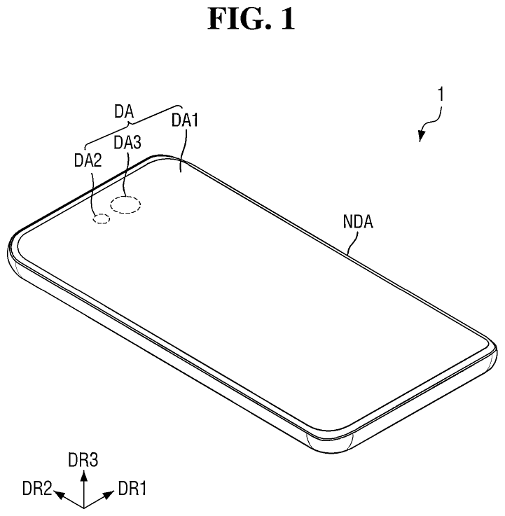

FIG. 1 is a perspective view illustrating an electronic device according to an embodiment.

Referring to FIG. 1, an electronic device 1 displays a moving image or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be included in the electronic device 1.

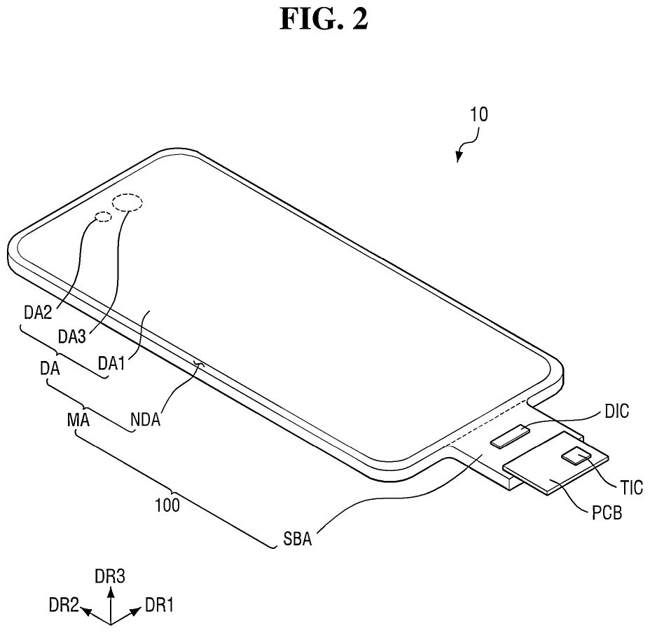

The electronic device 1 may include a display device 10 (see FIG. 2) providing a display screen. Examples of the display device may include an inorganic light emitting display, an organic light emitting display, a quantum dot light emitting display, a plasma display panel, a field emission display, and the like. Hereinafter, a case where an organic light emitting diode display is applied as an example of the display device will be described by way of example, but the present disclosure is not limited thereto, and the same technical spirit may be applied to other display devices if applicable.

A shape of the electronic device 1 may be variously modified. For example, the electronic device 1 may have a shape such as a rectangular shape with a width greater than a length, a rectangular shape with a length greater than a width, a square shape, a quadrangular shape with rounded corners (vertices), other polygonal shapes, or a circular shape. A shape of a display area DA of the electronic device 1 may also be similar to an overall shape of the electronic device 1. In FIG. 1, the electronic device 1 having a rectangular shape with a great length in a second direction DR2 has been illustrated.

In the drawings, a first direction DR1 and the second direction DR2 are horizontal directions, respectively, and cross each other. For example, the first direction DR1 and the second direction DR2 may be orthogonal to each other. In addition, a third direction DR3 may be a perpendicular direction crossing, for example, orthogonal to, the first direction DR1 and the second direction DR2. In the present specification, directions indicated by arrows of the first to third directions DR1, DR2, and DR3 may be referred to as one side, and directions opposite to one side may be referred to as the other side.

The electronic device 1 may include a display area DA and a non-display area NDA. The display area DA is an area in which a screen may be displayed, and the non-display area NDA is an area in which the screen is not displayed. The display area DA may also be referred to as an active area, and the non-display area NDA may also be referred to as a non-active area. The display area DA may occupy substantially the center of the electronic device 1.

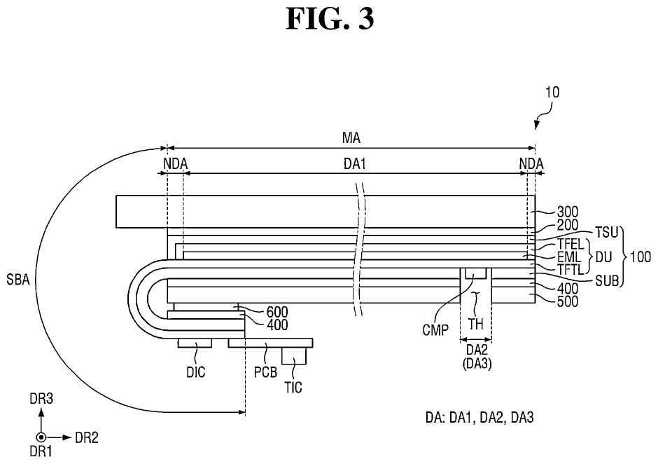

The display area DA may include a first display area DA1, a second display area DA2, and a third display area DA3. The second display area DA2 and the third display area DA3 may be areas in which a component CMP (see FIG. 3) for adding various functions to the electronic device 1 is disposed.

FIG. 2 is a perspective view illustrating a display device included in the electronic device according to an embodiment.

Referring to FIG. 2, the electronic device 1 according to an embodiment may include a display device 10. The display device 10 may provide a screen displayed on the electronic device 1. The display device 10 may have a shape similar to that of the electronic device 1 in plan view. For example, the display device 10 may have a shape similar to a rectangular shape having short sides in the first direction DR1 and long sides in the second direction DR2. A corner where the short side in the first direction DR1 and the long side in the second direction DR2 meet may be rounded with a curvature, but is not limited thereto, and may also be right-angled. The shape of the display device 10 in plan view is not limited to the rectangular shape, and may be a shape similar to other polygonal shapes, a circular shape, or an elliptical shape.

The display device 10 may include a display panel 100, a display driver DIC, a circuit board PCB, and a touch driver TIC.

The display panel 100 may include a main area MA and a sub-area SBA.

The main area MA may include a display area DA including pixels displaying an image and a non-display area NDA disposed around the display area DA. The display area DA may include a first display area DA1, a second display area DA2, and a third display area DA3. The display area DA may emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver supplying gate signals to gate lines and fan-out lines connecting the display driver DIC and the display area DA to each other.

The sub-area SBA may be an area extending from one side of the main area MA. The sub-area SBA may include a flexible material that may be bent, folded, and rolled. For example, when the sub-area SBA is bent, the sub-area SBA may overlap the main area MA in a thickness direction (third direction DR3). The sub-area SBA may include the display driver DIC and pad parts connected to the circuit board PCB. In another embodiment, the sub-area SBA may be omitted, and the display driver DIC and the pad parts may be disposed in the non-display area NDA.

The display driver DIC may output signals and voltages for driving the display panel 100. The display driver DIC may supply data voltages to data lines. The display driver DIC may supply source voltages to power lines and supply gate control signals to the gate driver. The display driver DIC may be formed as an integrated circuit (IC) and mounted on the display panel 100 in a chip on glass (COG) manner, a chip on plastic (COP) manner, or an ultrasonic bonding manner. As another example, the display driver DIC may be mounted on the circuit board PCB.

The circuit board PCB may be attached onto the pad parts of the display panel 100 using an adhesive member. As an example, the adhesive member may be a non-conductive film (NCF). As another example, the adhesive member may be an anisotropic conductive film (ACF) or a self assembly anisotropic conductive paste (SAP).

Lead lines of the circuit board PCB may be electrically connected to the pad parts of the display panel 100. The circuit board PCB may be a flexible printed circuit board, a printed circuit board, or a flexible film such as a chip on film.

The touch driver TIC may be mounted on the circuit board PCB. The touch driver TIC may be connected to a touch sensing unit of the display panel 100. The touch driver TIC may supply touch driving signals to a plurality of touch electrodes of the touch sensing unit and sense change amounts in capacitance between the plurality of touch electrodes. For example, the touch driving signal may be a pulse signal having a predetermined frequency. The touch driver TIC may decide whether or not an input has occurred and calculate input coordinates, based on the change amounts in capacitance between the plurality of touch electrodes. The touch driver TIC may be formed as an integrated circuit (IC).

FIG. 3 is a cross-sectional view illustrating the display device according to an embodiment.

Referring to FIG. 3, the display device 10 may include the display panel 100, an optical member 200, a window member 300, a lower film 400, a panel lower member 500, and a cover spacer 600.

The display panel 100 may include a substrate SUB, a display layer DU, and a touch sensing layer TSU (e.g., a touch layer). The display layer DU may include a thin film transistor layer TFTL (e.g., a circuit layer), a light emitting element layer EML, and a thin film encapsulation layer TFEL.

The substrate SUB may be a base substrate or a base member. The substrate SUB may be a flexible substrate that may be bent, folded, and rolled. For example, the substrate SUB may include a polymer resin such as polyimide (PI), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include gate lines, data lines, power lines, gate control lines, fan-out lines connecting the display driver DIC and the data lines to each other, and lead lines connecting the display driver DIC and the pad parts to each other.

Each of the thin film transistors may include a semiconductor region, a source electrode, a drain electrode, and a gate electrode. For example, when a gate driver is formed on one side of the non-display area NDA of the display panel 100, the gate driver may include thin film transistors.

The thin film transistor layer TFTL may be disposed in the display area DA, the non-display area NDA, and the sub-area SBA. In some embodiments, the thin film transistors of each of the pixels, the gate lines, the data lines, and the power lines of the thin film transistor layer TFTL may be disposed in the display area DA, but are not limited thereto. In some embodiments, the gate control lines and the fan-out lines of the thin film transistor layer TFTL may be disposed in the non-display area NDA, but are not limited thereto. In some embodiments, the lead lines of the thin film transistor layer TFTL may be disposed in the sub-area SBA, but are not limited thereto.

The light emitting element layer EML may be disposed on the thin film transistor layer TFTL. The light emitting element layer EML may include a plurality of light emitting elements each including a first electrode, a second electrode, and a light emitting layer to emit light and a pixel defining film defining the pixels. The plurality of light emitting elements of the light emitting element layer EML may be disposed in the display area DA.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The touch sensing layer TSU may be directly disposed on the thin film encapsulation layer TFEL. For example, the touch sensing layer TSU may be directly disposed on the thin film encapsulation layer TFEL and embedded in the display panel 100. The touch sensing layer TSU may include a plurality of touch electrodes for sensing a user's touch in a capacitance manner and touch lines connecting the plurality of touch electrodes and the touch driver TIC to each other. For example, the touch sensing layer TSU may sense the user's touch in a mutual capacitance manner or a self-capacitance manner.

In another embodiment, the touch sensing layer TSU may be disposed on a separate substrate disposed on the display layer DU. In this case, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The optical member 200 may be disposed on the display panel 100 in order to reduce external light reflection. The optical member 200 may be a polarizing film. The optical member 200 may include a first base member, a linear polarizer, a phase retardation film such as a λ/4 plate (quarter-wave plate), and a second base member. The first base member, the phase retardation film, the linear polarizer, and the second base member of the optical member 200 may be sequentially stacked on the display panel 100.

The window member 300 may be disposed on the optical member 200. The window member 300 may cover the display panel 100. A shape of the window member 300 may correspond to a shape of the display panel 100. The window member 300 may protect the display panel 100 from an external shock and provide an input surface to a user.

The window member 300 may have a transparent property so that light generated from the display panel 100 may be transmitted therethrough. The window member 300 may include glass or plastic. In some embodiments, when the window member 300 includes the glass, the window member 300 may include chemically ion-substituted tempered glass. In another embodiment, when the window member 300 includes the plastic, the window member 300 may include a polyimide (PI) film.

The lower film 400 may be disposed on a lower surface of the display panel 100. The lower film 400 may be disposed between the display panel 100 and the panel lower member 500. The lower film 400 may support the display panel 100.

The lower film 400 may include a first lower film and a second lower film spaced apart from each other along the second direction DR2. For example, the first lower film may be disposed in the main area MA of the display panel 100, and the second lower film may be disposed in the sub-area SBA of the display panel 100. The lower film 400 may not be disposed in an area in which the display panel 100 is bent in the sub-area SBA. The first lower film and the second lower film may face each other in the third direction DR3 in a state in which the display panel 100 is bent. The first lower film and the second lower film may overlap each other in the third direction DR3 in the state in which the display panel 100 is bent.

In an embodiment, the lower film 400 may include polyethylene terephthalate (PET), polyimide (PI), polycarbonate (PC), polyethylene (PE), polypropylene (PP), polysulfone (PSF), polymethyl methacrylate (PMMA), triacetyl cellulose (TAC), cycloolefin, or the like.

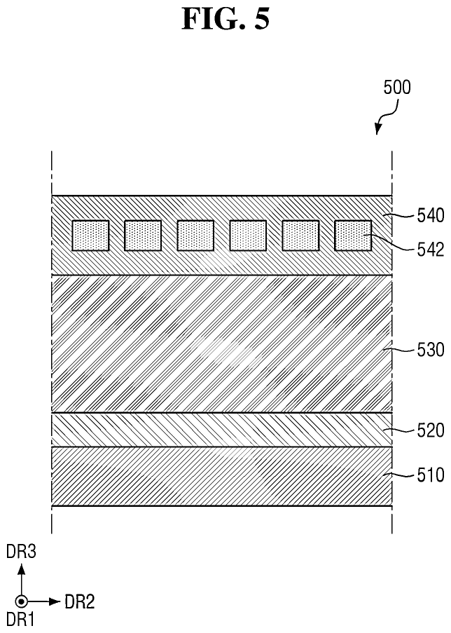

The panel lower member 500 may be disposed on a lower surface of the lower film 400. The panel lower member 500 may perform a heat dissipation function, an electromagnetic wave shielding function, a buffer function, a strength reinforcing function, and the like. A detailed structure and a function of the panel lower member 500 will be described in detail later with reference to FIG. 5.

The cover spacer 600 may control a bending (or bend) degree of the display panel 100 by compensating for a height difference between the panel lower member 500 and the sub-area SBA of the display panel 100 when the display panel 100 is bent. For example, by adjusting a thickness of the cover spacer 600, the panel lower member 500 and the sub-area SBA of the display panel 100 may be adjusted to be close to or distant from each other in the third direction DR3. Accordingly, a bending (or bend) degree of an area in which the display panel 100 is bent may be controlled.

In an embodiment, the cover spacer 600 may include a material having elasticity or a material capable of performing a support function. As an example, the cover spacer 600 may include thermoplastic elastomer, polystyrene, polyolefin, polyurethane thermoplastic elastomer, or the like. As another example, the cover spacer 600 may include polycarbonate (PC), polyimide (PI), polyethylene terephthalate (PET), or the like.

The display device 10 may further include a display driver DIC, a circuit board PCB, and a touch driver TIC disposed in the sub-area SBA of the display panel 100.

The display driver DIC, the circuit board PCB, and the touch driver TIC may be disposed in the sub-area SBA. The display driver DIC, the circuit board PCB, and the touch driver TIC may overlap the main area MA in the third direction DR3 by bending of the display panel 100.

The display driver DIC, the circuit board PCB, and the touch driver TIC have been described above with reference to FIG. 2, and a description thereof will thus be omitted.

The display device 10 may further include a through hole TH positioned in the second display area DA2 or the third display area DA3 and a component CMP disposed within the through hole TH.

The through hole TH may provide a space in which the component CMP may be disposed. It has been illustrated in FIG. 3 that the through hole TH penetrates through the panel lower member 500, the lower film 400, and the substrate SUB, but the present disclosure is not limited thereto. For example, the through hole TH may further penetrate through at least one of the display layer DU, the touch sensing layer TSU, and the optical member 200.

The component CMP may be disposed within the through hole TH. The component CMP may include an electronic component. For example, the component CMP may be an electronic component that uses light or sound. For example, the electronic component may include a sensor receiving light such as an infrared sensor, a camera receiving light and capturing an image, a sensor outputting and sensing light or sound to measure a distance or recognize a fingerprint or the like, a small lamp outputting light, a speaker outputting sound, or the like. The electronic component using the light may user light of various wavelength bands such as visible light, infrared light, and ultraviolet light. In some embodiments, the through hole TH may be a transmission area through which light or sound output from the component CMP to the outside or traveling from the outside toward the electronic component may be transmitted.

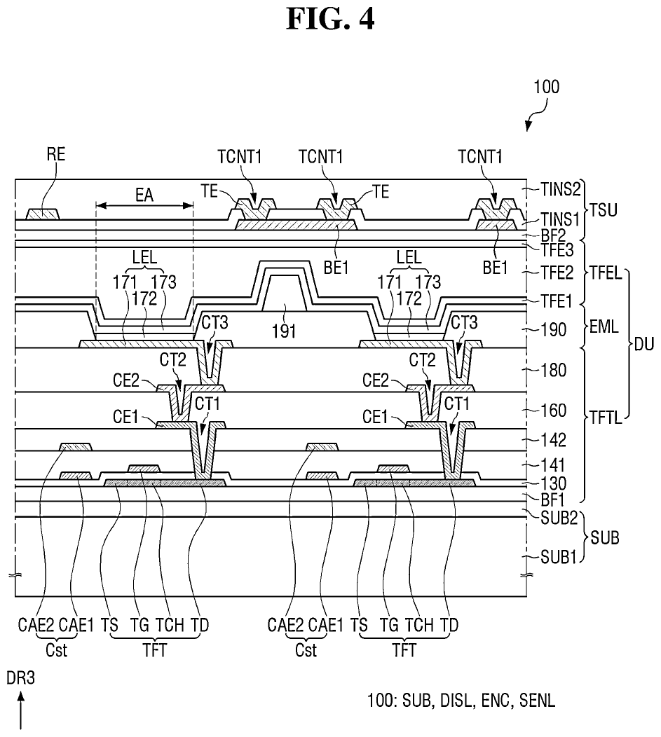

FIG. 4 is a cross-sectional view illustrating a display panel according to an embodiment.

Referring to FIG. 4, the display panel 100 may be an organic light emitting display panel including light emitting elements LEL each including an organic light emitting layer 172. However, the display panel 100 is not limited thereto, and may also be a light emitting display panel such as a quantum dot light emitting display panel including a quantum dot light emitting layer, an inorganic light emitting display panel including an inorganic semiconductor, and a micro or nano light emitting display panel using micro or nano light emitting diodes (micro LEDs or nano LEDs). Hereinafter, for convenience of explanation, a case where the display panel 100 is an organic light emitting display panel will be described by way of example.

The display panel 100 may include a substrate SUB, a display layer DU, and a touch sensing layer TSU.

The substrate SUB may include a first substrate SUB1 and a second substrate SUB2.

In an embodiment, the first substrate SUB1 may include a hard material, and the second substrate SUB2 may include a soft material. For example, the first substrate SUB1 may include glass, and the second substrate SUB2 may include a polymer resin, but the present disclosure is not limited thereto.

In another embodiment, the first substrate SUB1 and the second substrate SUB2 may include the same material. For example, both the first substrate SUB1 and the second substrate SUB2 may include a hard material or include a soft material.

In some embodiments, the substrate SUB may further include a buffer film disposed between the first substrate SUB1 and the second substrate SUB2. The buffer film may prevent moisture and oxygen from permeating from the outside into the light emitting element layer EML. The buffer film may be made of an inorganic material such as a silicon nitride layer, a silicon oxynitride layer, a silicon oxide layer, a titanium oxide layer, and an aluminum oxide layer. Alternatively, the buffer film may be formed as multiple films in which a plurality of layers of a silicon nitride layer, a silicon oxynitride layer, a silicon oxide layer, a titanium oxide layer, and an aluminum oxide layer are alternately stacked.

The display layer DU may include a thin film transistor layer TFTL (e.g., a circuit layer), a light emitting element layer EML, and a thin film encapsulation layer TFEL.

The thin film transistor layer TFTL (e.g., the circuit layer) may include a first buffer film BF1, thin film transistors TFT, a gate insulating film 130, a first interlayer insulating film 141, capacitors Cst, a second interlayer insulating film 142, a first data metal layer, a first organic film 160, a second data metal layer, and a second organic film 180.

The first buffer film BF1 may be disposed on the substrate SUB. The first buffer film BF1 may prevent moisture and oxygen from permeating from the outside into the light emitting element layer EML. The first buffer film BF1 may be made of an inorganic material such as a silicon nitride layer, a silicon oxynitride layer, a silicon oxide layer, a titanium oxide layer, and an aluminum oxide layer. Alternatively, the first buffer film BF1 may be formed as multiple films in which a plurality of layers of a silicon nitride layer, a silicon oxynitride layer, a silicon oxide layer, a titanium oxide layer, and an aluminum oxide layer are alternately stacked.

An active layer including a channel region TCH, a source region TS, and a drain region TD of the thin film transistor TFT may be disposed on the first buffer film BF1. The active layer may be made of polycrystalline silicon, single crystal silicon, low-temperature polycrystalline silicon, amorphous silicon, or an oxide semiconductor material. When the active layer includes the polycrystalline silicon or the oxide semiconductor material, the source region TS and drain region TD in the active layer may be conductive regions doped with ions or impurities to have conductivity.

The gate insulating film 130 may be disposed on the active layers of the thin film transistors TFT. The gate insulating film 130 may be formed as an inorganic film such as a silicon nitride layer, a silicon oxynitride layer, a silicon oxide layer, a titanium oxide layer, or an aluminum oxide layer.

A first gate metal layer including gate electrodes TG of the thin film transistors TFT, first capacitor electrodes CAE1 of the capacitors Cst, and scan lines may be disposed on the gate insulating film 130. The gate electrode TG of the thin film transistor TFT may overlap the channel region TCH in the third direction DR3. The first gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate metal layer. The first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including second capacitor electrodes CAE2 of the capacitors Cst may be disposed on the first interlayer insulating film 141. The second capacitor electrode CAE2 may overlap the first capacitor electrode CAE1 in the third direction DR3. Therefore, the capacitor Cst may be formed by the first capacitor electrode CAE1, the second capacitor electrode CAE2, and an inorganic insulating dielectric film disposed between the first capacitor electrode CAE1 and the second capacitor electrode CAE2 and serving as a dielectric film. The second gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second gate metal layer. The second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may include a plurality of inorganic films.

The first data metal layer including first connection electrodes CE1 and data lines may be disposed on the second interlayer insulating film 142. The first connection electrode CE1 may be connected to the drain region TD through a first connection contact hole CT1 penetrating through the gate insulating film 130, the first interlayer insulating film 141, and the second interlayer insulating film 142. The first data metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first organic film 160 for planarizing a step due to the thin film transistors TFT may be disposed on the first connection electrodes CE1. The first organic film 160 may be formed as an organic film made of an acrylic resin, an epoxy resin, a phenolic resin, a polyamide resin, a polyimide resin, or the like.

The second data metal layer including second connection electrodes CE2 may be disposed on the first organic film 160. The second data metal layer may be connected to the first connection electrode CE1 through a second contact hole CT2 penetrating through the first organic film 160. The second data metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second organic film 180 may be disposed on the second connection electrodes CE2. The second organic film 180 may be formed as an organic film made of an acrylic resin, an epoxy resin, a phenolic resin, a polyamide resin, a polyimide resin, or the like.

Meanwhile, the second data metal layer including the second connection electrodes CE2 and the second organic film 180 may be omitted.

The light emitting element layer EML is disposed on the thin film transistor layer TFTL. The light emitting element layer EML may include light emitting elements LEL and a pixel defining film 190.

Each of the light emitting elements LEL may include a pixel electrode 171, a light emitting layer 172, and a common electrode 173. Each of emission areas EA refers to an area in which the pixel electrode 171, the light emitting layer 172, and the common electrode 173 are sequentially stacked and holes from the pixel electrode 171 and electrons from the common electrode 173 are combined with each other in the light emitting layer 172 to emit light. In this case, the pixel electrode 171 may be an anode electrode, and the common electrode 173 may be a cathode electrode.

A pixel electrode layer including the pixel electrodes 171 may be formed on the second organic film 180. The pixel electrode 171 may be connected to the second connection electrode CE2 through a third connection hole CT3 penetrating through the second organic film 180. The pixel electrode layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

In a top emission structure in which light is emitted toward the common electrode 173 based on the light emitting layer 172, the pixel electrode 171 may be formed as a single layer made of molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO in order to increase reflectivity. The APC alloy is an alloy of silver (Ag), palladium (Pd), and copper (Cu).

The pixel defining film 190 serves to define the emission areas EA of the pixels. To this end, the pixel defining film 190 may be formed to expose partial areas of the pixel electrodes 171 on the second organic film 180. The pixel defining film 190 may cover edges of the pixel electrodes 171. The pixel defining film 190 may be disposed within the third contact holes CT3. That is, the third contact holes CT3 may be filled with the pixel defining film 190. The pixel defining film 190 may be formed as an organic film made of an acrylic resin, an epoxy resin, a phenolic resin, a polyamide resin, a polyimide resin, or the like.

A spacer 191 may be disposed on the pixel defining film 190. The spacer 191 may serve to support a mask during a process of manufacturing the light emitting layer 172. The spacer 191 may be formed as an organic film made of an acrylic resin, an epoxy resin, a phenolic resin, a polyamide resin, a polyimide resin, or the like.

The light emitting layer 172 is formed on the pixel electrode 171. The light emitting layer 172 may include an organic material to emit light of a predetermined color. For example, the light emitting layer 172 may include a hole transporting layer, an organic material layer, and an electron transporting layer. The organic material layer may include a host and a dopant. The organic material layer may include a material emitting predetermined light, and may be formed using a phosphorescent material or a fluorescent material.

The common electrode 173 is formed on the light emitting layer 172. The common electrode 173 may be formed to cover the light emitting layer 172. The common electrode 173 may be a common layer formed in common in the emission areas EA. A capping layer may be formed on the common electrode 173.

In the top emission structure, the common electrode 173 may be made of a transparent conductive material (TCO) such as ITO or indium zinc oxide (IZO) capable of transmitting light therethrough or a semi-transmissive conductive material such as magnesium (Mg), silver (Ag), or an alloy of magnesium (Mg) and silver (Ag). When the common electrode 173 is made of the semi-transmissive conductive material, emission efficiency may be increased by a micro cavity.

The thin film encapsulation layer TFEL may be disposed on the light emitting element layer EML. The thin film encapsulation layer TFEL may include at least one inorganic film TFE1 or TFE3 in order to prevent oxygen or moisture from permeating into the light emitting element layer EML. In addition, the thin film encapsulation layer TFEL may include at least one organic film TFE2 in order to protect the light emitting element layer EML from foreign substances such as dust. For example, the thin film encapsulation layer TFEL may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like.

The touch sensing layer TSU may be disposed on the thin film encapsulation layer TFEL. The touch sensing layer TSU may include a second buffer film BF2, first connection parts BE1, a first sensor insulating film TINS1, sensor electrodes TE and RE, and a second sensor insulating film TINS2.

The second buffer film BF2 may be disposed on the thin film encapsulation layer TFEL. The second buffer film BF2 may include at least one inorganic film. For example, the second buffer film BF2 may be formed as multiple films in which one or more inorganic films of a silicon nitride layer, a silicon oxynitride layer, a silicon oxide layer, a titanium oxide layer, and an aluminum oxide layer are alternately stacked. The second buffer film BF2 may be omitted.

The first connection parts BE1 may be disposed on the second buffer film BF2. The first connection parts BE1 may be formed as a single layer made of molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The first sensor insulating film TINS1 may be disposed on the first connection parts BE1. The first sensor insulating film TINS1 may be formed as an inorganic film such as a silicon nitride layer, a silicon oxynitride layer, a silicon oxide layer, a titanium oxide layer, or an aluminum oxide layer.

The sensor electrodes, that is, driving electrodes TE and sensing electrodes RE, may be disposed on the first sensor insulating film TNIS1. In addition, dummy patterns may be disposed on the first sensor insulating film TNIS1. The driving electrodes TE, the sensing electrodes RE, and the dummy patterns do not overlap the emission areas EA. Each of the driving electrodes TE, the sensing electrodes RE, and the dummy patterns may be formed as a single layer made of molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second sensor insulating film TINS2 may be disposed on the driving electrodes TE, the sensing electrodes RE, and the dummy patterns. The second sensor insulating film TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may be made of an acrylic resin, an epoxy resin, a phenolic resin, a polyamide resin, or a polyimide resin.

FIG. 5 is a cross-sectional view illustrating a panel lower member according to an embodiment.

Referring to FIG. 5 in addition to FIG. 3, the panel lower member 500 may include at least one functional layer. The functional layer may be a layer performing a heat dissipation function, an electromagnetic wave shielding function, a buffer function, a strength reinforcing function, a support function, an adhesive function, and the like. The functional layer may be a sheet layer made of a sheet, a film layer made of a film, a thin film layer, a coating layer, a panel, a plate, or the like. One functional layer may be formed as a single layer or be formed as a plurality of thin films or coating layers that are stacked. The functional layer may be, for example, a support substrate, a heat dissipation layer, an electromagnetic wave shielding layer, a shock absorbing layer, a coupling layer, or the like.

In some embodiments, the panel lower member 500 may include a shielding layer 510, an adhesive layer 520, a buffer layer 530, and a heat dissipation adhesive layer 540.

The shielding layer 510 may shield electromagnetic waves. The shielding layer 510 may include a material shielding electromagnetic waves and having excellent thermal conductivity. For example, the shielding layer 510 may include a metal thin film made of copper, nickel, ferrite, silver, or the like.

The adhesive layer 520 may be disposed between the shielding layer 510 and the buffer layer 530. The adhesive layer 520 may couple the shielding layer 510 and the buffer layer 530 to each other. In an embodiment, the adhesive layer 520 may include a polymer material classified as a silicone-based polymer material, a urethane-based polymer material, a SU polymer having a silicone-urethane hybrid structure, an acrylic polymer material, an isocyanate-based polymer material, a polyvinyl alcohol-based polymer material, a gelatin-based polymer material, a vinyl-based polymer material, a latex-based polymer material, a polyester-based polymer material, an aqueous polyester-based polymer material, and the like.

The buffer layer 530 may be disposed on the adhesive layer 520. The buffer layer 530 may prevent the display device 10 from being damaged by absorbing an external shock. The buffer layer 530 may be formed as a single layer or a plurality of stacked films.

In an embodiment, the buffer layer 530 may include a material capable of being elastically deformed. For example, the buffer layer 530 may include thermoplastic elastomer, polystyrene, polyolefin, polyurethane thermoplastic elastomers, polyamides, synthetic rubbers, polydimethylsiloxane, polybutadiene, polyisobutylene, poly(styrene-butadiene-styrene), polyurethanes, polychloroprene, polyethylene, silicone, or the like, and combinations thereof.

The heat dissipation adhesive layer 540 may be disposed on the buffer layer 530. The heat dissipation adhesive layer 540 may be disposed between the buffer layer 530 and the lower film 400. In some embodiments, when the lower film 400 is omitted, the heat dissipation adhesive layer 540 may be disposed between the buffer layer 530 and the display panel 100.

The heat dissipation adhesive layer 540 may couple the panel lower member 500 and the lower film 400 to each other or couple the panel lower member 500 and the display panel 100 to each other. The heat dissipation adhesive layer 540 may prevent heat generated by a plurality of components disposed below the panel lower member 500, such as an application chip, a camera, or a battery component, from reaching the display panel 100.

In some embodiments, the heat dissipation adhesive layer 540 may include an adhesive material and a material having an excellent heat dissipation function. For example, the heat dissipation adhesive layer 540 may include a heat dissipation layer 542 including a heat dissipation material and a coating layer surrounding the heat dissipation layer 542 and including an adhesive material.

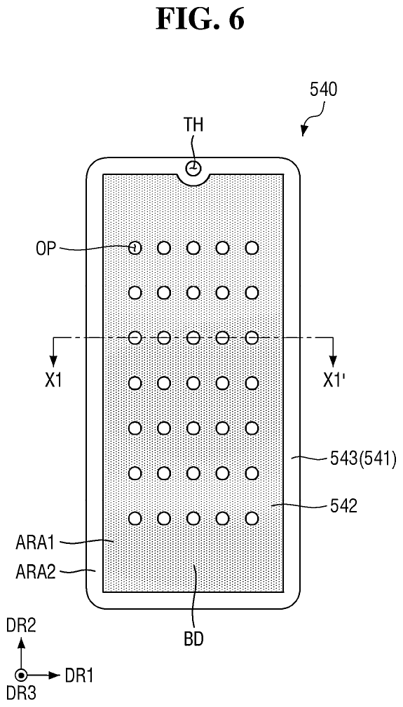

The heat dissipation adhesive layer 540 will be described later with reference to FIG. 6 and the like.

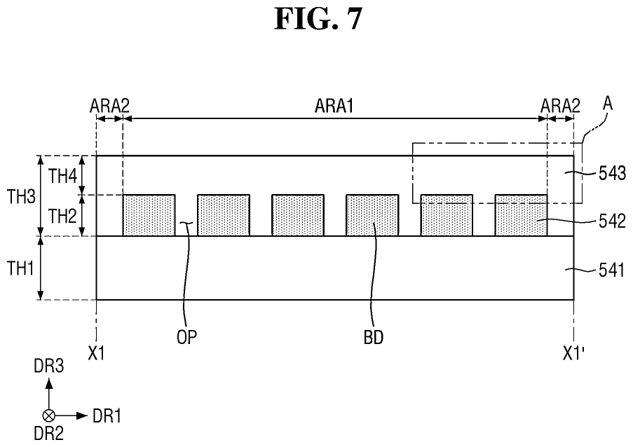

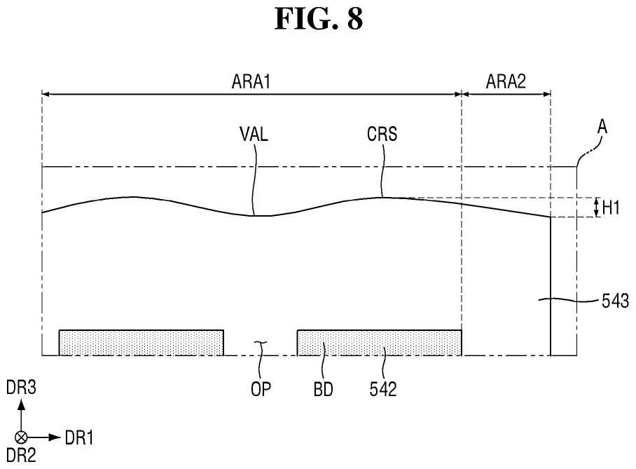

FIG. 6 is a plan view illustrating a heat dissipation adhesive layer according to an embodiment. FIG. 7 is a cross-sectional view taken along line X1-X1′ of FIG. 6. FIG. 8 is an enlarged view of area A of FIG. 7.

Referring to FIGS. 6 to 8 in addition to FIG. 5, the heat dissipation adhesive layer 540 according to an embodiment may include a first coating layer 541, a heat dissipation layer 542, and a second coating layer 543. The heat dissipation adhesive layer 540 may have a structure in which the heat dissipation layer 542 is surrounded by the first coating layer 541 and the second coating layer 543. For example, upper and lower surfaces and side surfaces of the heat dissipation layer 542 may be surrounded by the first coating layer 541 and the second coating layer 543. However, the present disclosure is not limited thereto, and at least portions of the upper and lower surfaces and the side surfaces of the heat dissipation layer 542 may also be exposed to the outside without being surrounded by the first coating layer 541 and the second coating layer 543.

The first coating layer 541 and the second coating layer 543 may include an adhesive or sticky material. The first coating layer 541 and the second coating layer 543 may include a thermosetting resin or an ultraviolet curable resin, but are not limited thereto. For example, the first coating layer 541 and the second coating layer 543 may include at least one of an epoxy resin, a phenoxy resin, an amino resin, a polyester resin, and a polyurethane resin as a curable resin. The first coating layer 541 and the second coating layer 543 according to the present embodiment may prevent delamination and decomposition of the heat dissipation layer 542 such as splitting or breaking of the heat dissipation layer 542 into a laminar structure due to intermolecular repulsion.

In an embodiment, the first coating layer 541 and the second coating layer 543 may include a highly heat-resistant heat dissipation adhesive having excellent heat conduction and heat dissipation characteristics. Accordingly, heat emitted by the heat dissipation layer 542 may be easily discharged to the outside through the first coating layer 541 and the second coating layer 543.

In some embodiments, the first coating layer 541 and the second coating layer 543 may include the same material. However, the present disclosure is not limited thereto, and the first coating layer 541 and the second coating layer 543 may include different materials.

In some embodiments, the first coating layer 541 and the second coating layer 543 may further include a light blocking material. For example, the first coating layer 541 and the second coating layer 543 may include a black pigment such as carbon black or a black dye. The first coating layer 541 and the second coating layer 543 according to the present embodiment may prevent components disposed below the heat dissipation adhesive layer 540 from being viewed through a display surface by further including the light blocking material.

The first coating layer 541 may support the heat dissipation layer 542. The first coating layer 541 may be disposed between the heat dissipation layer 542 and the buffer layer 530. The first coating layer 541 may couple the heat dissipation adhesive layer 540 and the buffer layer 530 to each other. The first coating layer 541 may be in contact with the lower surface of the heat dissipation layer 542.

The second coating layer 543 may cover the heat dissipation layer 542. In some embodiments, the second coating layer 543 may cover the upper surface of the heat dissipation layer 542. In some embodiments, the second coating layer 543 may cover the side surfaces of the heat dissipation layer 542. The second coating layer 543 may be in contact with the upper surface and the side surfaces of the heat dissipation layer 542.

In some embodiments, an embossed shape may be formed on an upper surface of the second coating layer 543. In a case where the embossed shape is formed on the upper surface of the second coating layer 543, when the heat dissipation adhesive layer 540 is attached to a lower portion of the lower film 400 or the display panel 100, the embossed shape of the upper surface of the second coating layer 543 may serve as an air passage to minimize bubbles on an interface. When the heat dissipation adhesive layer 540 is completely attached to the lower portion of the lower film 400 or the display panel 100, the embossed shape of the upper surface of the second coating layer 543, as illustrated in FIGS. 7 and 8, may collapse and become flat.

The heat dissipation layer 542 may be disposed on the first coating layer 541. The heat dissipation layer 542 may be interposed between the first coating layer 541 and the second coating layer 543. The heat dissipation layer 542 may be surrounded by the first coating layer 541 and the second coating layer 543.

The heat dissipation layer 542 may include a material having excellent heat conduction and heat dissipation characteristics. For example, the heat dissipation layer 542 may include at least one of graphite and carbon nanotubes.

In some embodiments, the heat dissipation layer 542 may include opening holes OP and a body portion BD. The body portion BD may surround the opening holes OP in plan view.

The opening hole OP may be a through hole penetrating through the heat dissipation layer 542 in the third direction DR3. The opening hole OP may be filled with the first coating layer 541 or the second coating layer 543 or a combination of both. The heat dissipation layer 542 according to the present embodiment may have high delamination strength by including the opening holes OP.

It has been illustrated in FIG. 6 that the opening hole OP has a circular shape in plan view, but the present disclosure is not limited thereto. For example, a shape of the opening hole OP in plan view may be modified into various shapes such as a polygonal shape such as a quadrangular shape or an elliptical shape.

In an embodiment, the number of opening holes OP may be plural. For example, as illustrated in FIG. 6, the plurality of opening holes OP may be disposed to be spaced apart from each other along a matrix direction. It has been illustrated in FIG. 6 that five opening holes OP are disposed along the first direction DR1, which is a short side direction (row direction), and seven opening holes OP are disposed along the second direction DR2, which is a long side direction (column direction), but the present disclosure is not limited thereto. In another embodiment, the plurality of opening holes OP may be arranged zigzag or be arranged randomly, and the number of opening holes OP may also variously modified.

In some embodiments, as illustrated in FIG. 6, the heat dissipation layer 542 may be smaller than the first coating layer 541 and the second coating layer 543 in plan view. For example, the heat dissipation adhesive layer 540 may include a first area ARA1 in which the heat dissipation layer 542 is disposed and a second area ARA2 in which the heat dissipation layer 542 is not disposed. The first area ARA1 may be surrounded by the second area ARA2. In the second area ARA2, the heat dissipation layer 542 may not be disposed, and only the first coating layer 541 and the second coating layer 543 may be disposed.

In some embodiments, the heat dissipation adhesive layer 540 may include a through hole TH disposed in the second area ARA2. The through hole TH of the heat dissipation adhesive layer 540 may be a hole penetrating through the first coating layer 541 and the second coating layer 543 in the third direction DR3. The through hole TH of the heat dissipation adhesive layer 540 may be a portion of the through hole TH of the second and third display areas DA2 and DA3 (see FIG. 3) described with reference to FIG. 3.

In an embodiment, a thickness of the heat dissipation adhesive layer 540 may be approximately 20 μm to 120 μm, but is not limited thereto. Each of a thickness TH1 of the first coating layer 541 and a thickness TH3 of the second coating layer 543 may be approximately 10 μm to 60 μm, but is not limited thereto.

In some embodiments, a thickness TH2 of the heat dissipation layer 542 may be smaller than the thickness TH3 of the second coating layer 543. For example, the thickness TH2 of the heat dissipation layer 542 may be approximately 5 μm to 50 μm, but is not limited thereto.

In the display device 10 according to the present embodiment, the heat dissipation adhesive layer 540 may include several height steps between an upper surface of the first coating layer 541 and the upper surface of the heat dissipation layer 542. For example, such height differences may be formed due to a height difference between the upper surface of the first coating layer 541 and the upper surface of the heat dissipation layer 542 formed by the thickness TH2 of the heat dissipation layer 542. Such height steps may be positioned at a boundary between the first area ARA1 and the second area ARA2 and boundaries between the body portion BD and the opening holes OP.

As illustrated in FIG. 7, in some embodiments, a thickness TH4 of the second coating layer 543 overlapping the body portion BD of the heat dissipation layer 542 may be smaller than the thickness TH3 of the second coating layer 543 disposed on the first coating layer 541. For example, the thickness TH4 of the second coating layer 543 that overlaps the body portion BD of the heat dissipation layer 542 may be smaller than the thickness TH3 of the second coating layer 543 that does not overlap the body portion BD of the heat dissipation layer 542. The thickness TH4 of the second coating layer 543 overlapping the body portion BD of the heat dissipation layer 542 may be smaller than the thickness TH3 of the second coating layer 543 disposed in the second area ARA2 and the thickness TH3 of the second coating layer 543 overlapping the opening hole OP.

In the display device 10 according to the present embodiment, the upper surface of the second coating layer 543 may be a substantially flat surface. For example, as illustrated in FIG. 8, the second coating layer 543 may include a ridge portion CRS and a valley portion VAL. The ridge portion CRS of the second coating layer 543 may overlap the body portion BD of the heat dissipation layer 542 in the third direction DR3, and the valley portion VAL of the second coating layer 543 may overlap the opening hole OP of the heat dissipation layer 542 or the second area ARA2 in the third direction DR3.

In some embodiments, a height difference H1 between the ridge portion CRS and the valley portion VAL may be within approximately 10% of the thickness TH3 of the second coating layer 543. As an example, the height difference H1 between the ridge portion CRS and the valley portion VAL may be within approximately 5 μm. When the height difference H1 between the ridge portion CRS and the valley portion VAL is within approximately 5 μm, a step between the ridge portion CRS and the valley portion VAL may not be viewed from the outside. In the present specification, that the upper surface of the second coating layer 543 is substantially flat may mean that the height difference H1 between the ridge portion CRS and the valley portion VAL is within approximately 5 μm or less.

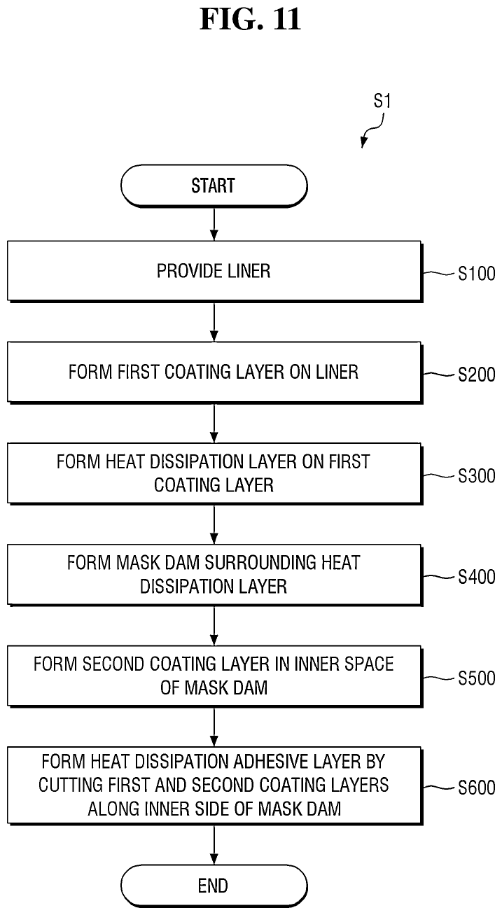

In the display device 10 according to the present embodiment, the second coating layer 543 may be formed by applying a liquid resin onto the first coating layer 541 and the heat dissipation layer 542 in a method S1 for manufacturing a display device to be described later. In this case, the ridge portion CRS and the valley portion VAL may be formed due to a height step due to the thickness TH2 of the heat dissipation layer 542. In the display device 10 according to the present embodiment, by minimizing the height difference H1 between the ridge portion CRS and the valley portion VAL, it is possible to prevent the step between the ridge portion CRS and the valley portion VAL of the second coating layer 543 from being viewed to the outside. A method of minimizing the height difference H1 between the ridge portion CRS and the valley portion VAL will be described later through a method S1 (see FIG. 11) for manufacturing a display device with reference to FIG. 11 and the like.

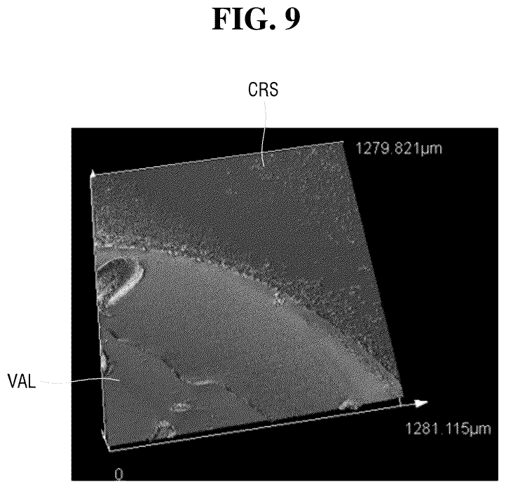

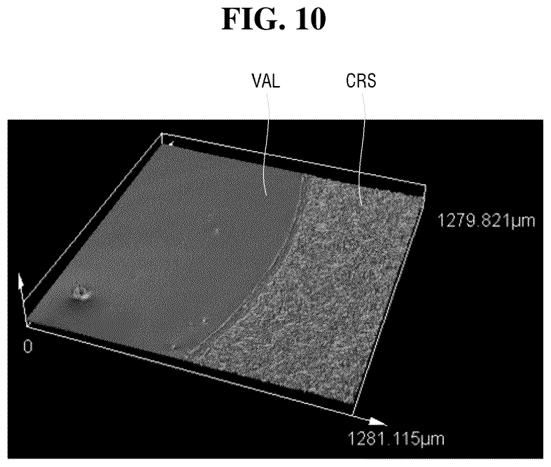

FIG. 9 is a photograph of a graph illustrating flatness of a heat dissipation adhesive layer according to the related art. FIG. 10 is a photograph of a graph illustrating flatness of the heat dissipation adhesive layer according to an embodiment.

Referring to FIGS. 9 and 10 in addition to FIGS. 6 to 8, FIG. 9 illustrates flatness of an upper surface of the heat dissipation adhesive layer 540 according to the related art, and FIG. 10 illustrates flatness of an upper surface of the heat dissipation adhesive layer 540 according to an embodiment. The heat dissipation adhesive layer 540 according to an embodiment has been manufactured by a method S1 (see FIG. 11) for manufacturing a display device to be described later. The heat dissipation adhesive layer 540 according to the related art has been manufactured by forming the second coating layer 543 without a mask dam MSD in a method S1 (see FIG. 11) for manufacturing a display device to be described later.

As illustrated in the graph of FIG. 9, the height difference H1 between the ridge portion CRS and the valley portion VAL in the heat dissipation adhesive layer 540 according to the related art may be approximately 20 μm. On the other hand, as illustrated in the graph of FIG. 10, the height difference H1 between the ridge portion CRS and the valley portion VAL in the heat dissipation adhesive layer 540 according to the present embodiment may be less than approximately 5 μm.

As such, in the display device 10 according to the present embodiment, by minimizing the height difference H1 between the ridge portion CRS and the valley portion VAL, it is possible to prevent the ridge portion CRS and the valley portion VAL of the second coating layer 543 from being viewed to the outside.

Hereinafter, a method of manufacturing a heat dissipation adhesive layer for a display device according to an embodiment for minimizing the height difference H1 between the ridge portion CRS and the valley portion VAL will be described with reference to FIG. 11 and the like.

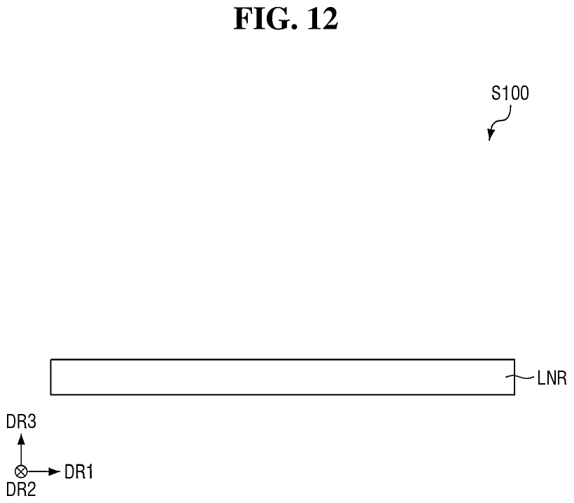

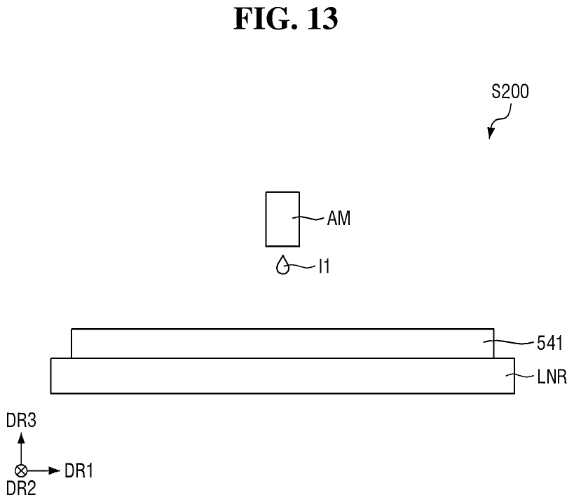

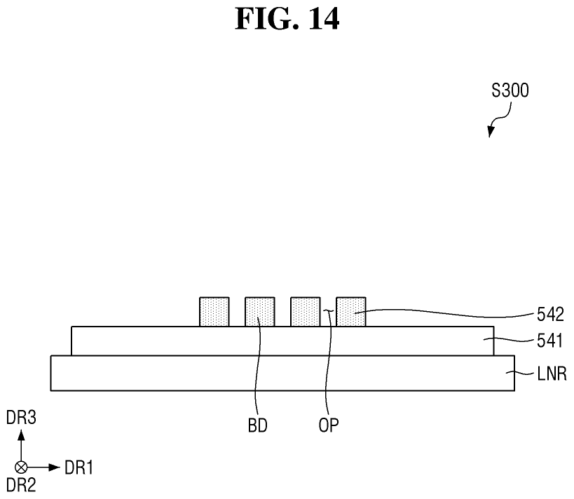

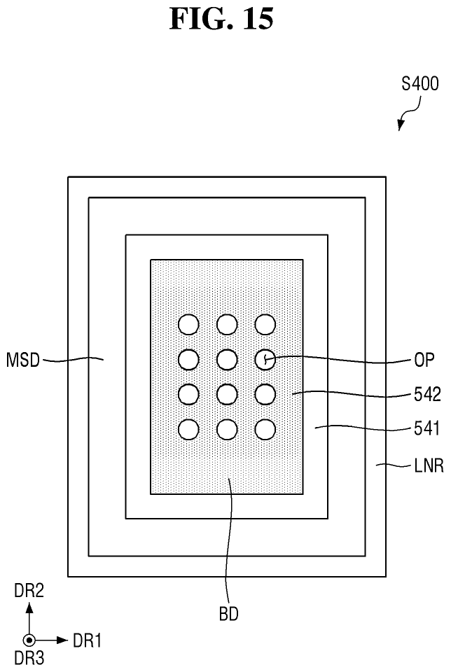

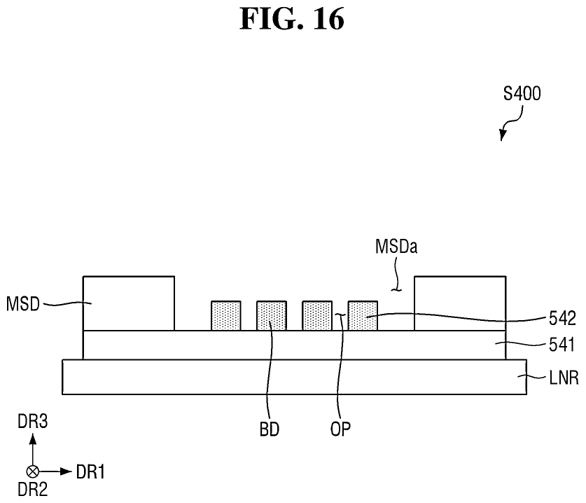

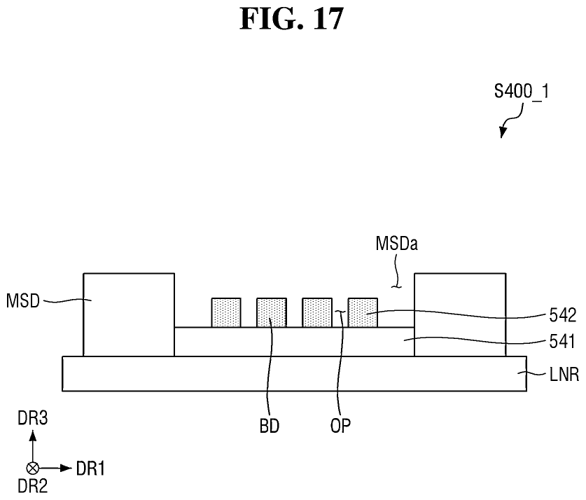

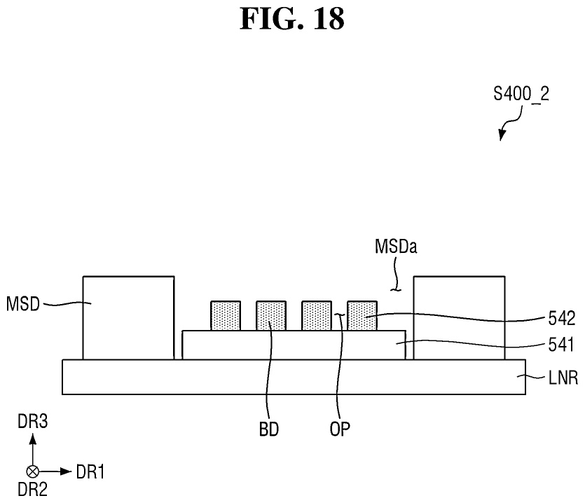

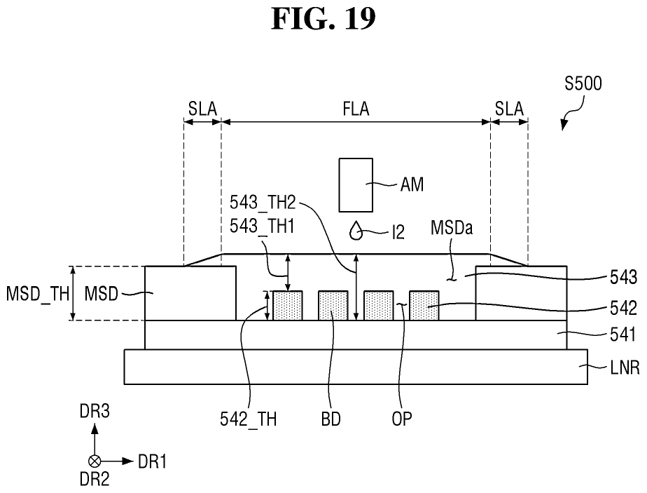

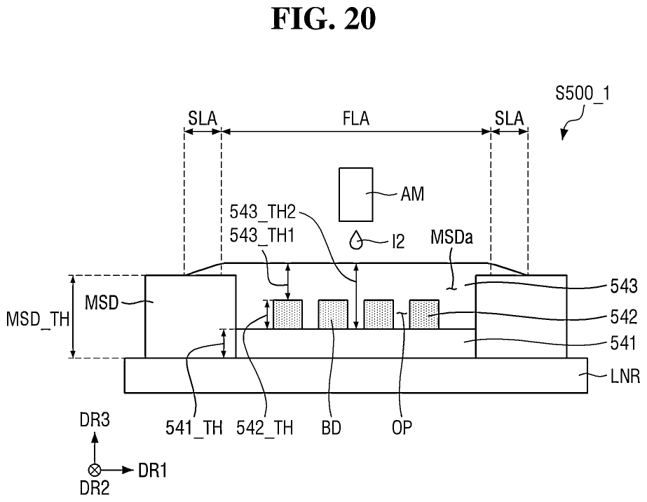

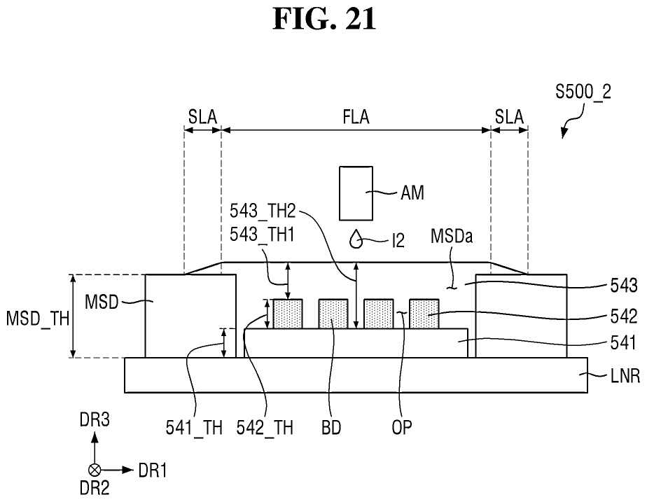

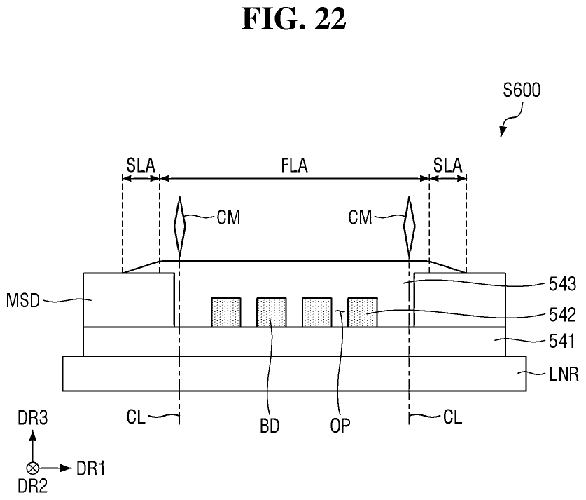

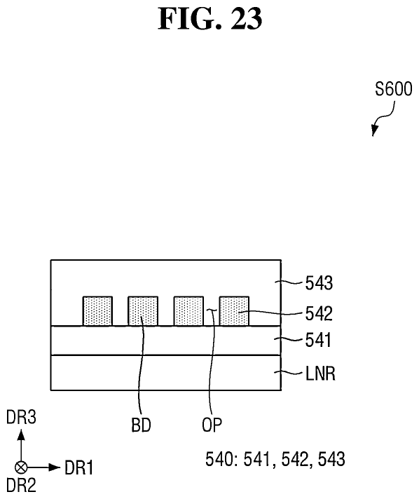

FIG. 11 is a flowchart illustrating a method of manufacturing a heat dissipation adhesive layer for a display device according to an embodiment. FIG. 12 is a cross-sectional view illustrating S100 of FIG. 11. FIG. 13 is a cross-sectional view illustrating S200 of FIG. 11. FIG. 14 is a cross-sectional view illustrating S300 of FIG. 11. FIG. 15 is a plan view illustrating S400 of FIG. 11. FIG. 16 is a cross-sectional view illustrating S400 of FIG. 11. FIG. 17 is a cross-sectional view illustrating S400_1 of a method of manufacturing a heat dissipation adhesive layer for a display device according to another embodiment. FIG. 18 is a cross-sectional view illustrating S400_2 of a method of manufacturing a heat dissipation adhesive layer for a display device according to still another embodiment. FIG. 19 is a cross-sectional view illustrating S500 of FIG. 11. FIG. 20 is a cross-sectional view illustrating S500_1 of a method of manufacturing a heat dissipation adhesive layer for a display device according to another embodiment. FIG. 21 is a cross-sectional view illustrating S500_2 of a method of manufacturing a heat dissipation adhesive layer for a display device according to still another embodiment. FIG. 22 is a cross-sectional view illustrating S600 of FIG. 11. FIG. 23 is a cross-sectional view illustrating S600 of FIG. 11.

Referring to FIGS. 11 to 23, a method S1 of manufacturing a display device according to an embodiment may include providing a liner (S100), forming a first coating layer on the liner (S200), forming a heat dissipation layer on the first coating layer (S300), forming a mask dam surrounding the heat dissipation layer (S400), forming a second coating layer in an inner space of the mask dam (S500), and forming a heat dissipation adhesive layer by cutting the first and second coating layers along an inner side of the mask dam (S600).

As illustrated in FIG. 12, in the providing of the liner (S100), the liner LNR may be provided. The liner LNR may be a support film for supporting the first coating layer 541 and the second coating layer 543 or a protective film for maintaining adhesive strength of the first coating layer 541 and the second coating layer 543, in a step of manufacturing and carrying the heat dissipation adhesive layer 540.

In some embodiments, the liner LNR may be a type of release film. For example, the liner LNR may include polyethylene terephthalate (PET), polycarbonate (PC), polyimide (PI), paper, or the like. In order to increase a release force of the liner LNR, a silicone solution treatment may be performed on an upper surface of the liner LNR or a release coating layer including a silicone-based resin may be formed on the upper surface of the liner LNR, but the present disclosure is not limited thereto.

As illustrated in FIG. 13, in the forming of the first coating layer on the liner (S200), the first coating layer 541 may be formed on the liner LNR.

The first coating layer 541 may be applied onto the liner LNR using an application device AM. In an embodiment, the first coating layer 541 may be applied in a liquid form onto the liner LNR and then cured by heat or ultraviolet rays. In another embodiment, the first coating layer 541 may be naturally cured.

For example, the application device AM may apply a first ink I1 onto the liner LNR. The first ink I1 may be cured by a separate heating device or ultraviolet irradiation device. Accordingly, the first coating layer 541 may be formed on the liner LNR.

In some embodiments, the application device AM may be one of a slot die coating device, an inkjet device, and a dispensing device.

In an embodiment, the first ink I1 and the first coating layer 541 may include at least one of an epoxy resin, a phenoxy resin, an amino resin, a polyester-based resin, and a polyurethane-based resin as a curable resin, but are not limited thereto.

As illustrated in FIG. 14, in the forming of the heat dissipation layer on the first coating layer (S300), the heat dissipation layer 542 may be formed on the first coating layer 541. The heat dissipation layer 542 may include at least one of graphite and carbon nanotubes.

In an embodiment, when the heat dissipation layer 542 includes the graphite, the heat dissipation layer 542 may be formed by coating the first coating layer 541 with graphene oxide paste. The graphene oxide paste may be reduced through heating, and the heat dissipation layer 542 may be formed by lowering a temperature of the reduced graphite to crystallize the graphite. In another embodiment, the heat dissipation layer 542 may be formed by directly carbonizing an organic insulating material such as polyimide (PI).

In some embodiments, after the heat dissipation layer 542 is formed, the opening holes OP penetrating through the heat dissipation layer 542 may be formed. The opening holes OP may be formed to penetrate through the heat dissipation layer 542 in the third direction DR3 by perforating the heat dissipation layer 542. Accordingly, the opening holes OP and the body portion BD surrounding the opening holes OP may be formed.

As illustrated in FIGS. 15 to 18, in the forming of the mask dam surrounding the heat dissipation layer (S400), the mask dam MSD may be disposed to surround the heat dissipation layer 542.

As illustrated in FIG. 15, the mask dam MSD may surround the heat dissipation layer 542 in plan view. The mask dam MSD may include an inner space MSDa in which the heat dissipation layer 542 is disposed. An inner side surface of the mask dam MSD may be spaced apart from an outer side surface of the heat dissipation layer 542. The inner side surface of the mask dam MSD may surround the outer side surface of the heat dissipation layer 542 in plan view. A size of the mask dam MSD may be smaller than or equal to a size of the liner LNR in plan view.

In an embodiment, as illustrated in FIG. 16, the mask dam MSD may be disposed on the first coating layer 541. In another embodiment, as illustrated in FIGS. 17 and 18, the mask dam MSD may be disposed on the liner LNR, and may be disposed to surround the first coating layer 541 and the heat dissipation layer 542. The inner side surface of the mask dam MSD may be in direct contact with an outer side surface of the first coating layer 541, as illustrated in FIG. 17, or may be disposed outside the outer side surface of the first coating layer 541 and spaced apart from the outer side surface of the first coating layer 541, as illustrated in FIG. 18.

As illustrated in FIGS. 19 to 21, in the forming of the second coating layer in the inner space of the mask dam (S500), the second coating layer 543 may be formed in the inner space MSDa of the mask dam MSD.

The second coating layer 543 may be applied to the inner space MSDa of the mask dam MSD using an application device AM. In an embodiment, the second coating layer 543 may be applied in a liquid form to the inner space MSDa of the mask dam MSD and then cured by heat or ultraviolet rays. In another embodiment, the second coating layer 543 may be naturally cured.

For example, the application device AM may apply a second ink 12 to the inner space MSDa of the mask dam MSD. The second ink 12 may be cured by a separate heating device or ultraviolet irradiation device. Accordingly, the second coating layer 543 may be formed in the inner space MSDa of the mask dam MSD.

In an embodiment, the second ink 12 and the second coating layer 543 may include at least one of an epoxy resin, a phenoxy resin, an amino resin, a polyester resin, and a polyurethane resin as a curable resin, but are not limited thereto.

In an embodiment, when the mask dam MSD is disposed on the first coating layer 541 as illustrated in FIG. 19 or the inner side surface of the mask dam MSD is in direct contact with a side surface of the first coating layer 541 as illustrated in FIG. 20, the second coating layer 543 may be disposed on the first coating layer 541. For example, the second coating layer 543 may be in contact with an upper surface of the first coating layer 541, side surfaces and an upper surface of the heat dissipation layer 542, and the inner side surface of the mask dam MSD.

In another embodiment, when the mask dam MSD is disposed on the liner LNR and is spaced apart from the outer side surface of the first coating layer 541 as illustrated in FIG. 21, the second coating layer 543 may be disposed on the liner LNR. For example, the second coating layer 543 may be in contact with the upper surface of the liner LNR, the outer side surfaces of the first coating layer 541, the side surfaces and the upper surface of the heat dissipation layer 542, and the inner side surface of the mask dam MSD.

In some embodiments, a thickness MSD_TH of the mask dam MSD may be greater than or equal to a thickness 542_TH of the heat dissipation layer 542. By making the thickness MSD_TH of the mask dam MSD greater than or equal to the thickness 542_TH of the heat dissipation layer 542, it is possible to minimize the height difference H1 between the ridge portion CRS (see FIG. 8) and the valley portion VAL (see FIG. 8) of the second coating layer 543 described with reference to FIG. 8 and the like. When the mask dam MSD is disposed on the liner LNR as illustrated in FIGS. 20 and 21, the thickness MSD_TH of the mask dam MSD may be greater than or equal to the sum of a thickness 541_TH of the first coating layer 541 and the thickness 542_TH of the heat dissipation layer 542.

For example, by disposing the mask dam MSD, it is possible to prevent the second ink I2 having a liquid form from being spread in the first direction DR1 and the second direction DR2. Accordingly, the second ink I2 may be spread evenly on the body portion BD and the opening hole OP despite a height step between the body portion BD and the opening hole OP. Accordingly, despite a difference between a thickness 543_TH1 of the second coating layer 543 disposed on the body portion BD and a thickness 543_TH2 of the second coating layer 543 disposed in the opening hole OP, the upper surface of the second coating layer 543 may become substantially flat.

In some embodiments, the second coating layer 543 may include a flat portion FLA and a sloped portion SLA due to other intermolecular attraction forces such as surface tension. For example, the second coating layer 543 may be substantially flat at the center, and a slope angle of a sloped surface may be deepened toward the outside. In an embodiment, the flat portion FLA may refer to a portion where the height difference H1 (see FIG. 8) between the ridge portion CRS (see FIG. 8) and the valley portion VAL (see FIG. 8) is within approximately 10% of the thickness of the second coating layer 543, and the sloped portion SLA may refer to a portion where the height difference H1 (see FIG. 8) between the ridge portion CRS (see FIG. 8) and the valley portion part VAL (see FIG. 8) exceeds approximately 10% of the thickness of the second coating layer 543.

In some embodiments, the second coating layer 543 may be formed to overflow the inner space MSDa of the mask dam MSD. For example, the upper surface of the second coating layer 543 may be positioned at a higher level than an upper surface of the mask dam MSD. The second coating layer 543 may cover at least a portion of the upper surface of the mask dam MSD. In the method S1 for manufacturing a display device according to the present embodiment, the sloped portion SLA is positioned on the upper surface of the mask dam MSD, such that the upper surface of the second coating layer 543 may be formed to be flatter.

As illustrated in FIGS. 22 and 23, in the forming of the heat dissipation adhesive layer by cutting the inner side of the mask (S600), the heat dissipation adhesive layer 540 may be formed by cutting the liner LNR, the first coating layer 541, and the second coating layer 543 positioned inside the mask dam MSD.

For example, the first coating layer 541 and the second coating layer 543 may be cut using a cutting member CM. A cutting line CL of the cutting member CM may be positioned inside the inner side surface of the mask dam MSD. The cutting line CL of the cutting member CM may be surrounded by the inner side surface of the mask dam MSD in plan view, and may surround the heat dissipation layer 542.

In some embodiments, the cutting line CL of the cutting member CM may overlap the flat portion FLA. Accordingly, the upper surface of the second coating layer 543 of the heat dissipation adhesive layer 540 may be substantially flat, and the ridge portion CRS (see FIG. 8) and the valley portion VAL (see FIG. 8) of the second coating layer 543 may be prevented from being viewed to the outside.

After a cutting process, the mask dam MSD and the cut liner LNR along with the first coating layer 541 and second coating layer 543 of an outer side portion may be removed.

In some embodiments, a separate liner LNR may be further disposed on the second coating layer 543. By disposing the liners LNR on upper and lower surfaces of the heat dissipation adhesive layer 540, adhesive strength of the first coating layer 541 and the second coating layer 543 may be maintained when the heat dissipation adhesive layer 540 is carried.

When the mask dam MSD is disposed in a process of forming the second coating layer 543 according to the method S1 for manufacturing a display device according to the present embodiment, the height difference H1 (see FIG. 8) between the ridge portion CRS (see FIG. 8) and the valley portion VAL (see FIG. 8) may be within approximately 3 μm. Accordingly, the height difference H1 (see FIG. 8) between the ridge portion CRS (see FIG. 8) and the valley portion VAL (see FIG. 8) is formed within 5 μm, and thus, the step between the ridge portion CRS and the valley portion VAL may not be viewed from the outside.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A method of manufacturing a heat dissipation adhesive layer for a display device, comprising:
providing a liner, a first coating layer on the liner, and a heat dissipation layer on the first coating layer;
forming a mask dam surrounding the heat dissipation layer; and
forming a second coating layer inside the mask dam.

2. The method of manufacturing a heat dissipation adhesive layer for a display device of claim 1, wherein the heat dissipation layer includes a body portion and an opening hole penetrating through the body portion.

3. The method of manufacturing a heat dissipation adhesive layer for a display device of claim 2, wherein the second coating layer fills the opening hole.

4. The method of manufacturing a heat dissipation adhesive layer for a display device of claim 3, wherein an upper surface of the second coating layer includes a ridge portion overlapping the body portion and a valley portion overlapping the opening hole.

5. The method of manufacturing a heat dissipation adhesive layer for a display device of claim 4, wherein a height difference between the ridge portion and the valley portion is 5 μm or less.

6. The method of manufacturing a heat dissipation adhesive layer for a display device of claim 1, wherein the second coating layer includes a flat portion and a sloped portion disposed on one side of the flat portion.

7. The method of manufacturing a heat dissipation adhesive layer for a display device of claim 6, wherein an upper surface of the second coating layer includes a ridge portion and a valley portion positioned at a lower level than the ridge portion, and
in the flat portion, a height difference between the ridge portion and the valley portion is 5 μm or less.

8. The method of manufacturing a heat dissipation adhesive layer for a display device of claim 6, further comprising cutting the second coating layer along an inner side of the mask dam.

9. The method of manufacturing a heat dissipation adhesive layer for a display device of claim 8, wherein a cutting line of the second coating layer overlaps the flat portion of the second coating layer.

10. The method of manufacturing a heat dissipation adhesive layer for a display device of claim 1, wherein an upper surface of the second coating layer is higher than an upper surface of the mask dam.

11. The method of manufacturing a heat dissipation adhesive layer for a display device of claim 10, wherein the second coating layer covers at least a portion of the upper surface of the mask dam.

12. The method of manufacturing a heat dissipation adhesive layer for a display device of claim 1, wherein a thickness of the mask dam is greater than or equal to a thickness of the second coating layer.

13. The method of manufacturing a heat dissipation adhesive layer for a display device of claim 1, wherein the mask dam is directly disposed on an upper surface of the first coating layer.

14. The method of manufacturing a heat dissipation adhesive layer for a display device of claim 1, wherein the mask dam is directly disposed on an upper surface of the liner, and surrounds the first coating layer.

15. The method of manufacturing a heat dissipation adhesive layer for a display device of claim 14, wherein an inner side surface of the mask dam is spaced apart from a side surface of the first coating layer.

16. A display device comprising:
a display panel; and
a panel lower member including a heat dissipation adhesive layer and disposed on a rear surface of the display panel, wherein
the heat dissipation adhesive layer includes a first coating layer, a heat dissipation layer disposed on the first coating layer, and a second coating layer covering the heat dissipation layer, and
an upper surface of the second coating layer is a flat surface.

17. The display device of claim 16, wherein
the upper surface of the second coating layer includes a ridge portion and a valley portion, and
the ridge portion is positioned at a higher level than the valley portion.

18. The display device of claim 17, wherein a height difference between the ridge portion and the valley portion is 10% or less of a thickness of the second coating layer.

19. The display device of claim 18, wherein the height difference between the ridge portion and the valley portion is 5 μm or less.

20. The display device of claim 16, wherein
the panel lower member further includes:
a shielding layer;
an adhesive layer disposed on the shielding layer, and
a buffer layer disposed on the adhesive layer, and
the heat dissipation adhesive layer is disposed on the buffer layer.
